(19) United States
(12) Patent Application Publication
(10) Pub. No.: US 2010/0301429 A1
(43) Pub. Date: Dec. 2, 2010

(54) SEMICONDUCTOR DEVICE AND METHOD OF MANUFACTURING THE SAME

(75) Inventor: TOSHIHIDE NABATAME, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/728,198

(22) Filed: Mar. 20, 2010

(30) Foreign Application Priority Data
May 29, 2009 (JP) JP2009-130808

(51) Int. Cl. H01L 29/78; H01L 21/336

(52) U.S. Cl. 257/411; 438/591; 438/287; 257/413; 257/E21.409; 257/E29.255

(57) ABSTRACT

In a p-channel-type field-effect transistor having a metal gate electrode, a technique capable of stably obtaining a desired threshold voltage is provided. On a gate insulating film composed of a HfSiON film and formed on a semiconductor substrate, there is formed a metal gate electrode partially having a conductive film with a Me₁₋ₓAlₓO_{y} (0.2≦x≦0.75, 0.2≦y≦1.5) composition having a Me-O—Al—O-Me bond or a metal gate electrode partially having a conductive film with a Me₁₋ₓAlₓN_{1-z}O_{z} (0.2≦x≦0.75, 0.1≦z≦0.9) composition having a Me-O—Al—N-Me bond.

### CROSS-REFERENCE TO RELATED APPLICATION

The present application claims priority from Japanese Patent Application No. 2009-130808 filed on May 29, 2009, the content of which is hereby incorporated by reference into this application.

### TECHNICAL FIELD OF THE INVENTION

The present invention relates to a semiconductor device and a method of manufacturing the same. More particularly, the present invention relates to a technique effectively applied to a p-channel-type field-effect transistor having a gate electrode composed of metal films and a gate insulating film composed of a high dielectric film, and a method of manufacturing the p-channel-type field-effect transistor.

### BACKGROUND OF THE INVENTION

For example, Japanese Patent Application Laid-Open Publication No. 2008-258487 (Patent Document 1) discloses a technique of forming a gate electrode on a gate insulating film composed of a hafnium-based oxynitride, the gate electrode being composed of a metal selected from a group consisting of Ru (ruthenium), Ir (iridium), Pt (platinum), Pd (palladium), Re (rhenium), W (tungsten), Mo (molybdenum), Ni (nickel), Co (cobalt), and TiN (titanium nitride), and containing Al (aluminum) or a rare earth element as an additive element.

Also, J. K. Schaeffer et al., Microelectronic Engineering 84, 2007, p. 2196 to 2200 (Non-Patent Document 1) discloses that a required threshold voltage can be obtained by using a MoON (molybdenum oxynitride) film having a higher work function than that of a Mo film for a gate electrode of a p-channel-type field-effect transistor.

Further, H.-C. Wen et al., 2007 Symposium on VLSI Technology Digest of Technical Papers, 2007, p. 160 to 161 (Non-Patent Document 2) discloses that an effective work function of a p-channel-type field-effect transistor is increased by using a material composed of MoN to which Al is added, for a gate electrode.

### SUMMARY OF THE INVENTION

In recent years, in a miniaturized planar-type field-effect transistor having a gate length of 30 nm or shorter, a structure has been studied in which, for example, an insulating material generally called a High-k dielectric film having a higher dielectric constant than that of SiO₂ (silicon dioxide) is used for the gate insulating film, and a metal is used for the gate electrode instead of polycrystalline Si.

Incidentally, when a metal is used for the gate electrode, the work function of the metal is one large factor determining the threshold voltage of the field-effect transistor. Various materials such as TiN, TiSiN, TaSiN (tantalum silicon nitride), TaC (tantalum carbide), W, and Mo are candidates of the material used for the gate electrode, and each of the materials basically has a unique work function. More particularly, MoON (for example, see the Non-Patent Document 1) or MoAlN (molybdenum aluminum nitride) (for example, see the Non-Patent Document 2) by which a relatively high work function can be obtained is highly expected as the material for the gate electrode of the p-channel-type field-effect transistor.

However, the Mo element has a lot of valences of +2, +3, +4, +5, and +6, and therefore, a composition of MoON is significantly affected by a condition (reducing or oxidizing character) of an atmosphere gas in processes of manufacturing the field-effect transistor, and therefore, wide structural change is caused from a metal (Mo) having a small work function to a semiconductor (MoO₃) in the composition of MoON. As a result, it is difficult to form a MoON film having a stable composition as the material of the gate electrode.

Also, by using the material composed of MoN to which Al is added for the gate insulating film, the work function of the p-channel-type field-effect transistor is increased. However, the required threshold voltage of the p-channel-type field-effect transistor is not always obtained.

A preferred aim of the present invention is to provide a technique capable of stably obtaining a desired threshold voltage in a p-channel-type field-effect transistor having a metal gate electrode.

The above and other preferred aims and novel characteristics of the present invention will be apparent from the description of the present specification and the accompanying drawings.

An embodiment of the typical ones of the inventions disclosed in the present application will be briefly described as follows.

This embodiment is for a semiconductor device having a p-channel-type field-effect transistor in which a metal gate electrode and a gate insulating film composed of a high dielectric film having a higher dielectric constant than that of SiO₂ are provided on a main surface of a semiconductor substrate. The metal gate electrode is composed of a conductive film with a Me₁₋ₓAlₓO_{y} composition having a bond composed of a metal element, Al element, and O (oxygen) element, and a ratio “x” of the Al element is 0.2 or larger and 0.75 or smaller and a ratio “y” of the O element is 0.2 or larger and 1.5 or smaller.

Also, this embodiment is for a semiconductor device having a p-channel-type field-effect transistor in which a metal gate electrode and a gate insulating film composed of a high dielectric film having a higher dielectric constant than that of SiO₂ are provided on a main surface of a semiconductor substrate. The metal gate electrode is composed of a conductive film with a Me₁₋ₓAlₓN_{1-z}O_{z} composition having a bond composed of a metal element, Al element, N (nitrogen) element, and O element, and a ratio “x” of the Al element is 0.2 or larger and 0.75 or smaller and a ratio “z” of the O element is 0.1 or larger and 0.9 or smaller.

Further, this embodiment is for a method of manufacturing a semiconductor device having a p-channel-type field-effect transistor on a main surface of a semiconductor substrate. First, a gate insulating film composed of a high dielectric film having a higher dielectric constant than that of SiO₂ is formed on the main surface of the semiconductor substrate. Subsequently, a first metal film and an Al film are sequentially formed on the gate insulating film, and then, a thermal treatment is applied to the semiconductor substrate at a temperature of 400° C. or lower for oxidizing the Al film to form an AlO_{y} film. Subsequently, a second metal film is formed on the AlO_{y} film, and then, a thermal treatment is applied to the semiconductor substrate at a temperature of 600° C. or higher to form the metal gate electrode on the gate insulating film, the metal gate electrode being composed of the conductive film with the Me₁₋ₓAlₓO_{y} (0.2≦x≦0.75, 0.2≦y ≦1.5) composition.

Still further, this embodiment is for a method of manufacturing a semiconductor device having a p-channel-type field-effect transistor on a main surface of a semiconductor substrate. First, a gate insulating film composed of a high dielectric film having a higher dielectric constant than that of SiO₂ is formed on the main surface of the semiconductor substrate. Subsequently, a first metal nitride film and an AlN_{z} film are sequentially formed on the gate insulating film, and then, a thermal treatment is applied to the semiconductor substrate at a temperature of 400° C. or lower for oxidizing the AlN_{z} film to form an AlN_{1-z}O_{z} film. Subsequently, a second metal nitride film is formed on the AlN_{1-z}O_{z} film, and then, a thermal treatment is applied to the semiconductor substrate at a temperature of 600° C. or higher to form the metal gate electrode on the gate insulating film, the metal gate electrode being composed of the conductive film with the Me₁₋ₓAl_{z}N_{1-z}O_{z} (0.2≦x≦0.75, 0.1≦z≦0.9) composition.

The effects obtained by typical aspects of the present invention will be briefly described below.

In a p-channel-type field-effect transistor having a metal gate electrode, a desired threshold voltage can be stably obtained.

### BRIEF DESCRIPTIONS OF THE DRAWINGS

FIG. 1 is a cross-sectional view of a principal part illustrating a CMIS device according to a first embodiment of the present invention;

FIG. 2 is a graph chart explaining a relation between a work function of a Mo₁₋ₓAlₓO_{y} film and an Al concentration or O concentration according to the first embodiment of the present invention;

FIG. 3 is a schematic diagram illustrating so as to enlarge a part of a gate electrode in a pMIS according to the first embodiment of the present invention;

FIG. 4 is a cross-sectional view of the principal part illustrating a manufacturing step for the CMIS device according to the first embodiment of the present invention;

FIG. 5 is a cross-sectional view of the principal part of the same portion as FIG. 4 in the manufacturing step for the CMIS device continued from FIG. 4;

FIG. 6 is a cross-sectional view of the principal part of the same portion as FIG. 4 in the manufacturing step for the CMIS device continued from FIG. 5;

FIG. 7 is a cross-sectional view of the principal part of the same portion as FIG. 4 in the manufacturing step for the CMIS device continued from FIG. 6;

FIG. 8 is a cross-sectional view of the principal part of the same portion as FIG. 4 in the manufacturing step for the CMIS device continued from FIG. 7;

FIG. 9 is a cross-sectional view of the principal part of the same portion as FIG. 4 in the manufacturing step for the CMIS device continued from FIG. 8;

FIG. 10 is a cross-sectional view of the principal part of the same portion as FIG. 4 in the manufacturing step for the CMIS device continued from FIG. 9;

FIG. 11 is a cross-sectional view of the principal part of the same portion as FIG. 4 in the manufacturing step for the CMIS device continued from FIG. 10;

FIG. 12 is a cross-sectional view of the principal part of the same portion as FIG. 4 in the manufacturing step for the CMIS device continued from FIG. 11;

FIG. 13 is a cross-sectional view of the principal part of the same portion as FIG. 4 in the manufacturing step for the CMIS device continued from FIG. 12;

FIG. 14 is a cross-sectional view of the principal part of the same portion as FIG. 4 in the manufacturing step for the CMIS device continued from FIG. 13;

FIG. 15 is a cross-sectional view of the principal part of the same portion as FIG. 4 in the manufacturing step for the CMIS device continued from FIG. 14;

FIG. 16 is a cross-sectional view of the principal part of the same portion as FIG. 4 in the manufacturing step for the CMIS device continued from FIG. 15;

FIG. 17 is a cross-sectional view of the principal part of the same portion as FIG. 4 in the manufacturing step for the CMIS device continued from FIG. 16;

FIG. 18 is a cross-sectional view of a principal part illustrating a CMIS device according to a second embodiment of the present invention;

FIG. 19 is a graph chart explaining a relation between a work function of a Mo₁₋ₓAlₓN_{1-z}O_{z} film and an Al concentration or O concentration according to the second embodiment of the present invention;

FIG. 20 is a schematic diagram illustrating so as to enlarge a part of a gate electrode in a pMIS according to the second embodiment of the present invention;

FIG. 21 is a cross-sectional view of the principal part illustrating a manufacturing step for the CMIS device according to the second embodiment of the present invention;

FIG. 22 is a cross-sectional view of the principal part of the same portion as FIG. 21 in the manufacturing step for the CMIS device continued from FIG. 21;

FIG. 23 is a cross-sectional view of the principal part of the same portion as FIG. 21 in the manufacturing step for the CMIS device continued from FIG. 22;

FIG. 24 is a cross-sectional view of the principal part of the same portion as FIG. 21 in the manufacturing step for the CMIS device continued from FIG. 23;

FIG. 25 is a cross-sectional view of the principal part of the same portion as FIG. 21 in the manufacturing step for the CMIS device continued from FIG. 24;

FIG. 26 is a cross-sectional view of the principal part of the same portion as FIG. 21 in the manufacturing step for the CMIS device continued from FIG. 25;

FIG. 27 is a cross-sectional view of the principal part of the same portion as FIG. 21 in the manufacturing step for the CMIS device continued from FIG. 26;

FIG. 28 is a cross-sectional view of the principal part of the same portion as FIG. 21 in the manufacturing step for the CMIS device continued from FIG. 27; and

FIG. 29 is a cross-sectional view of the principal part of the same portion as FIG. 21 in the manufacturing step for the CMIS device continued from FIG. 28.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Further, in the following embodiments, a metal insulator semiconductor field effect transistor (MISFET) representing a field-effect transistor is abbreviated as “MIS”, a p-channel-type MISFET is abbreviated as “pMIS”, and an n-channel-type MISFET is abbreviated as “nMIS”. Still further, in the following embodiments, the term “wafer” mainly indicates a silicon (Si) monocrystalline wafer and it indicates not only the same but also a silicon on insulator (SOI) wafer, an insulating film substrate for forming an integrated circuit thereon, or the like. The shape of the wafer includes not only a circular shape or a substantially circular shape but also a square shape, a rectangular shape, and the like.

Still further, components having the same function are denoted by the same reference symbols throughout the drawings for describing the embodiment, and the repetitive description thereof will be omitted. Hereinafter, embodiments of the present invention will be described in detail with reference to the accompanying drawings.

### First Embodiment

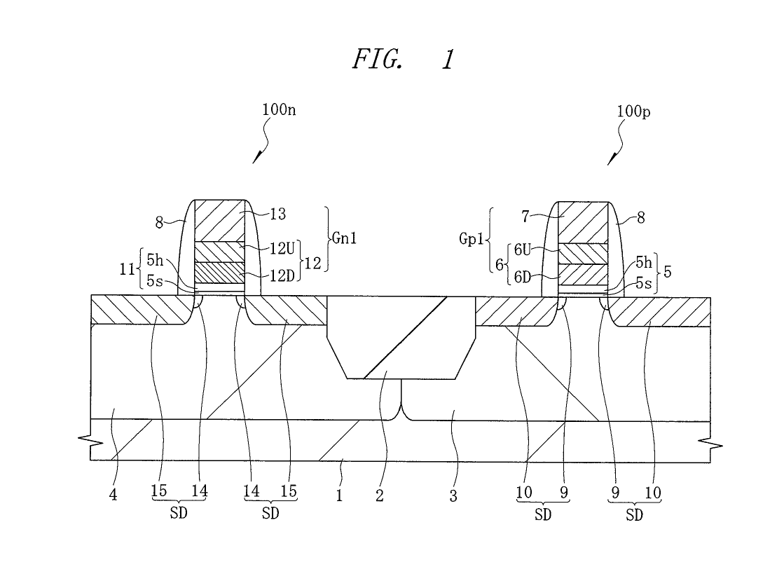

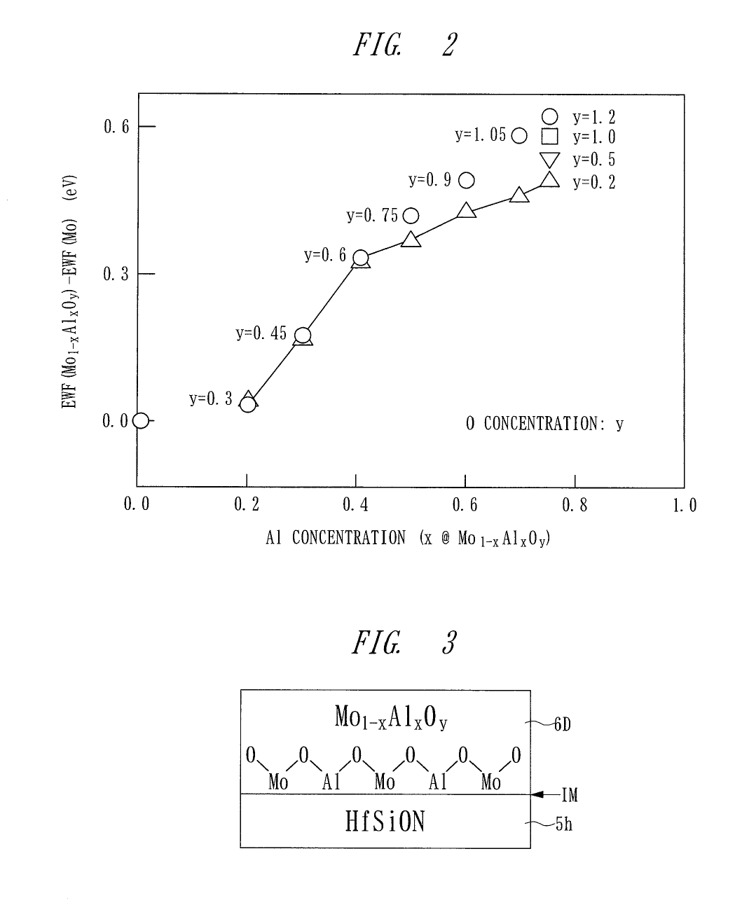

A complementary metal insulator semiconductor (CMIS) device according to a first embodiment will be described with reference to FIGS. 1 to 3. FIG. 1 is a cross-sectional view of a principal part of the CMIS device, FIG. 2 is a graph chart explaining a relation between a work function of a Mo₁₋ₓAlₓO_{y} film and an Al concentration or O concentration, and FIG. 3 is a schematic diagram illustrating so as to enlarge a part of a gate electrode in a pMIS .

An element isolator 2 is formed on a main surface of a semiconductor substrate 1. The element isolator 2 has a function of preventing interference between elements formed on the semiconductor substrate 1, and the element isolator 2 is formed by, for example, a shallow trench isolation (STI) method of forming a trench in the semiconductor substrate 1 and burying an insulating film in the trench. An active region isolated by the element isolator 2 becomes the pMIS formation region or the nMIS formation region.

An n-type well 3 to be a semiconductor region is formed on the main surface of the semiconductor substrate 1 in the pMIS formation region, and a p-type well 4 to be a semiconductor region is formed on the main surface of the semiconductor substrate 1 in the nMIS formation region. An n-type impurity such as P (phosphorus) or As (arsenic) is doped into the n-type well 3, and a p-type impurity such as B (boron) is doped into the p-type well 4.

Next, a configuration of a pMIS 100p formed in the pMIS formation region will be described. As illustrated in FIG. 1, a gate insulating film 5 is formed on the n-type well 3, which is formed on the main surface of the semiconductor substrate 1 in the pMIS formation region.

The gate insulating film 5 is mainly composed of, for example, a high dielectric film 5h having a higher dielectric constant than that of SiO₂. As the high dielectric film 5h, for example, a hafnium-based insulating film such as a HfO₂ film, a HfON film, a HfSiO film, or a HfSiON film is used. Between the semiconductor substrate 1 and the high dielectric film 5h, an oxide film 5s such as a SiO₂ film is formed. When the semiconductor substrate 1 and the high dielectric film 5h directly contact with each other, mobility in the pMIS may be decreased. However, by interposing the oxide film 5s between the semiconductor substrate 1 and the high dielectric film 5h, the mobility decrease can be prevented. A thickness of the oxide film 5s is, for example, about 0.7 nm.

A metal gate electrode 6 is formed on the gate insulating film 5. The metal gate electrode 6 has a stacked structure constituted by a lower-layer metal gate electrode 6D and an upper-layer metal gate electrode 6U.

The lower-layer metal gate electrode 6D is composed of a conductive Me₁₋ₓAlₓO_{y} film containing Al element, O element, and a metal element (hereinafter, may referred to as “Me”), and a ratio “x” of the Al element is 0.2≦x≦0.75 and a ratio “y” of the 0 element is 0.2≦y≦1.5. The metal element is, for example, any of Mo, Ru, and Ir.

FIG. 2 illustrates the graph chart explaining dependency of the Al or O concentration with respect to a difference between work functions of a Mo film and the Mo₁₋ₓAlₓO_{y} film formed by using the Mo element as the metal element. As illustrated in FIG. 2, the work function of the Mo₁₋ₓAlₓO_{y} film in which Al and O elements are added to a Mo film is larger than that of the Mo film, and further, that of the Mo₁₋ₓAlₓO_{y} film increases as each concentration of the Al or O element contained in the Mo₁₋ₓAlₓO_{y} film increases. Therefore, by adjusting each concentration of the Al or O element contained in the Mo₁₋ₓAlₓO_{y} film, a desired work function of the Mo₁₋ₓAlₓO_{y} film larger than that of the Mo film can be obtained. As a result, a desired threshold voltage in the pMIS can be obtained.

It is considered that a reason for the larger work function of the Mo₁₋ₓAlₓO_{y} film than that of the Mo film is because, as illustrated in FIG. 3, a Mo—O—Al—O—Mo bond is formed in a region of the lower-layer metal gate electrode 6D within about 0.5 nm distance from an interface “IM” between the lower-layer metal gate electrode 6D (Mo₁₋ₓAlₓO_{y} film) and the gate insulating film 5h, so that the Mo—O bond is enhanced. The inventors of the present application confirmed an increasing concentration gradient of the Al and O concentrations in a vicinity of the interface IM in the Mo₁₋ₓAlₓO_{y} film by secondary ion-microprobe mass spectrometer (SIMS) analysis.

Also, as seen from the above-described FIG. 2, the work function of the Mo₁₋ₓAlₓO_{y} film depends on the Al concentration more than the O concentration. That is, the O concentration is low when the Al concentration in the Mo₁₋ₓAlₓO_{y} film is low, and the O concentration is increased as the Al concentration is increased. Therefore, in order to add a large amount of the O element to the Mo₁₋ₓAlₓO_{y} film for forming the Mo—O—Al—O—Mo bond, it is required to increase the Al concentration in the Mo₁₋ₓAlₓO₇ film.

Note that it is mostly preferable to obtain the ratio “x” of the Al element and the ratio “y” of the O element over the entire Mo₁₋ₓAlₓO_{y} film. However, the ratios may be obtained at least in the region of the lower-layer metal gate electrode 6D within about 0.5 nm distance from the interface IM between the lower-layer metal gate electrode 6D and the gate insulating film 5h.

While the upper-layer metal gate electrode 6U is composed of, for example, a TiN film, it is not limited to the film. For example, the upper-layer metal gate electrode 6U may be composed of, for example, any of a TaN film, a TaSiN film, a TiAlN film, a HfN film, a NiₓSi₁₋ₓ film, a PtSi film, NiₓTa₁₋ₓSi film, a NiₓPt₁₋ₓ Si film, a HfSi film, a WSi film, an IrₓSi₁₋ₓ film, a TaGe (tantalum germanium) film, a TaC, film, a Mo film, and a W film.

Further, a silicon gate electrode 7 is formed on the metal gate electrode 6. The silicon gate electrode 7 is composed of a polycrystalline Si film to which an impurity of, for example, about 1×10²⁰ cm⁻³ is doped. Therefore, a gate electrode Gp1 in the pMIS 100p has a stacked structure constituted by the metal gate electrode 6 and the silicon gate electrode 7.

A sidewalls 8 composed of, for example, an insulating film is formed on both sidewalls of the gate electrode Gp1. A p-type extension region 9 to be a semiconductor region is formed in the semiconductor substrate 1 (n-type well 3) immediately below each sidewall 8, and a p-type diffusion region 10 is formed outside the p-type extension region 9. A p-type impurity such as B is doped into the p-type extension region 9 and the p-type diffusion region 10, and the p-type impurity is doped into the p-type diffusion region 10 with a higher concentration than that of the p-type extension region 9. By the p-type extension region 9 and the p-type diffusion region 10, source/drain regions SD in the pMIS 100p each having a lightly doped drain (LDD) structure are formed.

Subsequently, a configuration of an nMIS 100n formed in the nMIS formation region will be described. As illustrated in FIG. 1, a gate insulating film 11 is formed on the p-type well 4 which is formed on the main surface of the semiconductor substrate 1 in the nMIS formation region.

The gate insulating film 11 is mainly composed of, for example, a high dielectric film 5h having a higher dielectric constant than that that of SiO₂. As the high dielectric film 5h, for example, a hafnium-based insulating film such as a HfO₂ film, a HfON film, a HfSiO film, or a HfSiON film is used. An oxide film 5s such as a SiO₂ film is formed between the semiconductor substrate 1 and the high dielectric film 5h.

A metal gate electrode 12 is formed on the gate insulating film 11. The metal gate electrode 12 has a stacked structure constituted by a lower-layer metal gate electrode 12D and an upper-layer metal gate electrode 12U. The lower-layer metal gate electrode 12D is composed of, for example, a TaSiN film. However, it is not limited to the film. The lower-layer metal gate electrode 12D may be composed of, for example, any of a TiN film, a TaN film, a TaSiN film, a TiAlN film, a HfN film, a NiₓSi₁₋ₓ film, a PtSi film, a NiₓTa₁₋ₓSi film, a NiₓPt₁₋ₓSi film, a HfSi film, a WSi film, an IrₓSi₁₋ₓ film, a TaGe film, a TaC, film, a Mo film, and a W film. Also, the upper-layer metal gate electrode 12U is composed of the same electrode material as that of the upper-layer metal gate electrode 6U positioned on an upper layer of the metal gate electrode 6 constituting a part of the gate electrode Gp1 in the above-described pMIS 100p.

Further, a silicon gate electrode 13 is formed on the metal gate electrode 12. The silicon gate electrode 13 is composed of the same electrode material as that of the silicon gate electrode 7 constituting another part of the gate electrode Gp1 in the above-described pMIS 100p. Therefore, a gate electrode Gn1 in the nMIS 100n has a stacked structure constituted by the metal gate electrode 12 and the silicon gate electrode 13.

A sidewall 8 composed of, for example, an insulating film is formed on both sidewalls of the gate electrode Gn1. An n-type extension region 14 to be a semiconductor region is formed in the semiconductor substrate 1 (p-type well 4) immediately below each sidewall 8, and an n-type diffusion region 15 is formed outside the n-type extension region 14. An n-type impurity such as P or As is doped into the n-type extension region 14 and the n-type diffusion region 15, and the n-type impurity is doped into the n-type diffusion regions 15 with a higher concentration than that of the n-type extension regions 14. By the n-type extension regions 14 and the n-type diffusion regions 15, source/drain regions SD in the nMIS 100n each having a LDD structure are formed.

Next, a method of manufacturing the CMIS device according to the first embodiment will be described in the order of steps with reference to FIGS. 4 to 17. FIGS. 4 to 17 are cross-sectional views of the principal part of the CMIS device.

First, as illustrated in FIG. 4, there is prepared the semiconductor substrate (at this time, a semiconductor thin plate having a substantially circular plane shape called a semiconductor wafer) 1 in which a p-type impurity such as B is doped into, for example, monocrystalline Si. Next, the element isolator 2 is formed in the main surface of the semiconductor substrate 1. The element isolator 2 is composed of, for example, SiO₂ and formed by, for example, a shallow trench isolation (STI) method, a local oxidization of silicon (LOCOS) method, or others. FIG. 4 illustrates the element isolator 2 formed by the STI method of burying the trench formed in the semiconductor substrate 1 by the SiO₂ film. Active regions are isolated by the element isolator 2, so that the pMIS formation region and the nMIS formation region are formed.

Next, the n-type well 3 is formed in the pMIS formation region by using a photolithography method and ion implantation method. The n-type well 3 is a semiconductor region to which an n-type impurity such as P or As is doped. Similarly, the p-type well 4 is formed in the nMIS formation region by using a photolithography method and ion implantation method. The p-type well 4 is a semiconductor region to which a p-type impurity such as B is doped.

Next, a SiO₂ film 16 is formed on the main surface of the semiconductor substrate 1 by using, for example, a thermal oxidation method. A thickness of the SiO₂ film 16 is, for example, 1 nm or thinner, and a typical thickness thereof is, for example, about 0.7 nm. Subsequently, a high dielectric film, for example, HfSiON film 17 is formed on the SiO₂ film 16 by using, for example, a chemical vapor deposition (CVD) method or an atomic layer deposition (ALD) method. A thickness of the HfSiON film 17 is, for example, 5 nm or thinner, and a typical thickness thereof is, for example, about 2.0 to 2.5 nm. Instead of the HfSiON film 17, another hafnium-based insulating film such as a HfON film, a HfSiO film, or a HfO₂ film can be used.

Next, a thermal treatment is applied to the semiconductor substrate 1. The thermal treatment is applied, for example, at 850° C. for about 5 seconds in N₂ atmosphere. By this thermal treatment, defects of the HfSiON film 17 can be repaired.

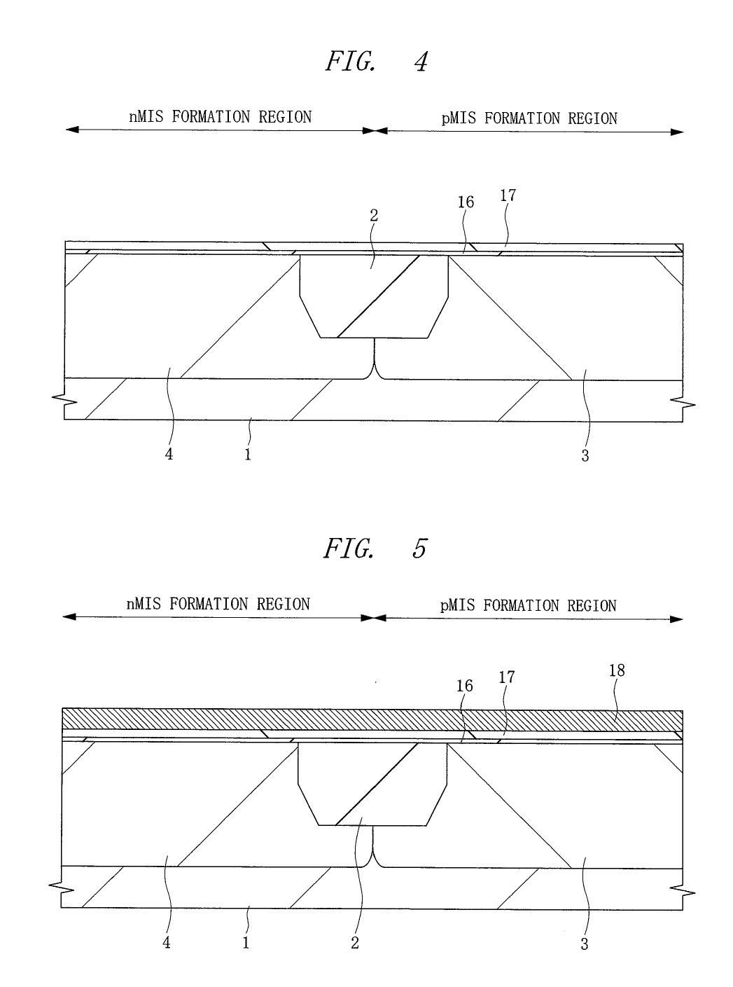

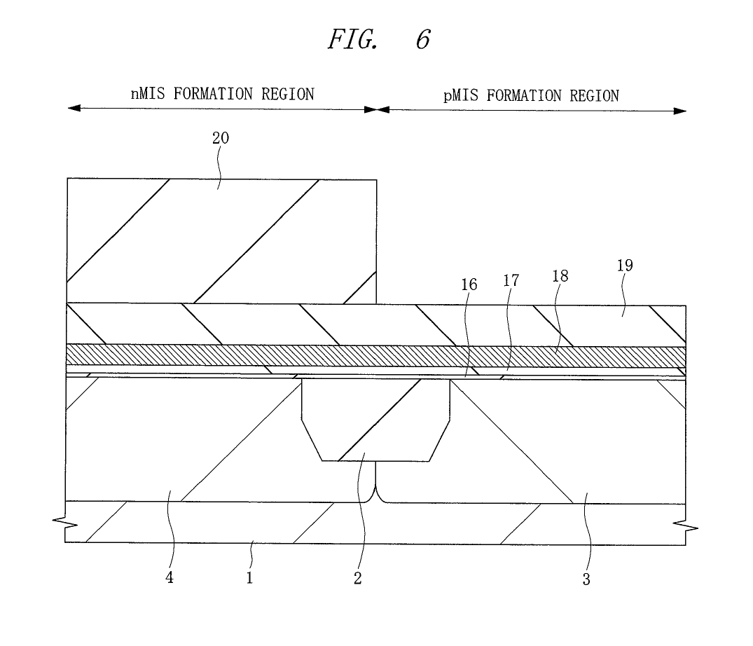

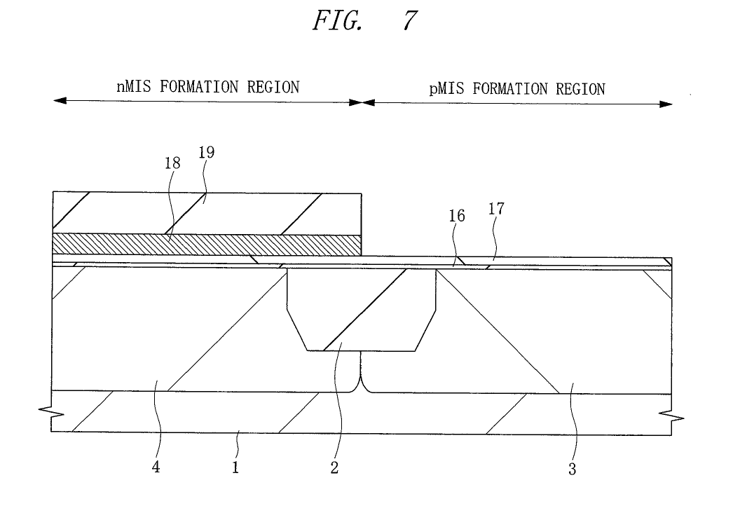

Next, as illustrated in FIG. 5, a TaSiN film 18 is formed on the HfSiON film 17 by using, for example, a sputtering method. A thickness of the TaSiN film 18 is, for example, about 10 nm. Instead of the TaSiN film 18, for example, a TiN film, a TaN film, a TaSiN film, a TiAlN film, a HfN film, a NiₓSi₁₋ₓ film, a PtSi film, NiₓTa₁₋ₓSi film, a NiₓPt₁₋ₓ S1 film, a HfSi film, a WSi film, an IrₓSi₁₋ₓ film, a TaGe film, a TaC, film, a Mo film, a W film, or others can be used.

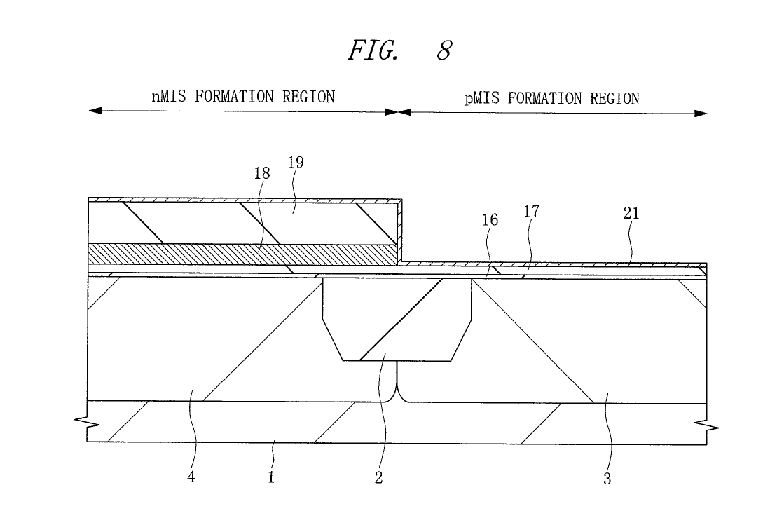

Next, as illustrated in FIG. 6, a SiN film 19 is formed on the TaSiN film 18 by using, for example, a CVD method. A thickness of the SiN film 19 is, for example, about 30 nm. Subsequently, a resist pattern 20 covering the nMIS formation region is formed by using a photolithography method.

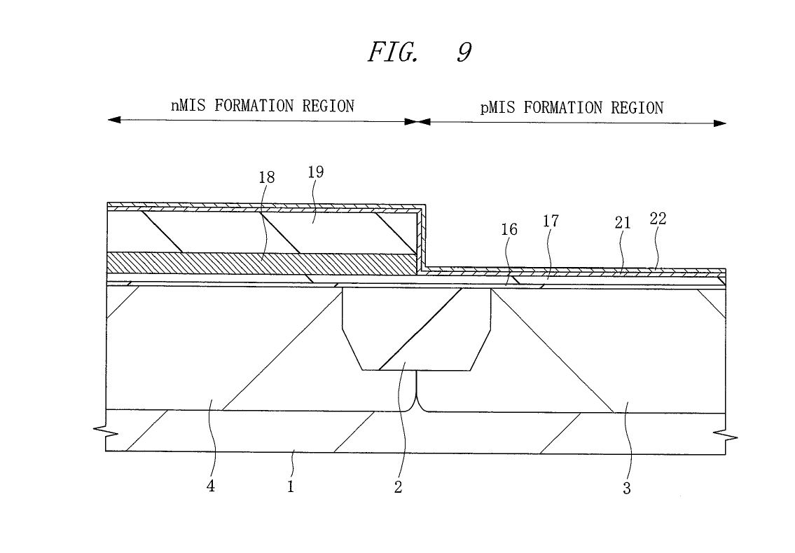

Next, as illustrated in FIG. 7, the SiN film 19 and the TaSiN film 18 in the pMIS formation region exposed from the resist pattern 20 are removed with using the resist pattern 20 as a mask by using, for example, a dry etching method, and then, the resist pattern 20 is removed.

Next, as illustrated in FIG. 8, a first Mo film 21 is formed on the HfSiON film 17 in the pMIS formation region and on the SiN film 19 in the nMIS formation region by using, for example, a sputtering method. A thickness of the first Mo film 21 is, for example, about 1 nm.

Next, as illustrated in FIG. 9, an Al film 22 is formed on the first Mo film 21 by using, for example, a sputtering method. A thickness of the Al film 22 is, for example, about 0.1 to 1 nm.

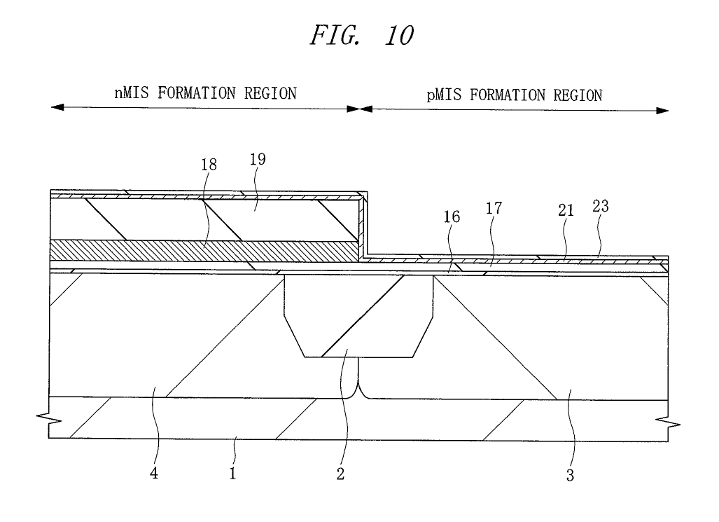

Next, as illustrated in FIG. 10, an oxidation treatment is applied to the semiconductor substrate 1. The oxidation treatment is applied at 400° C. or lower, for example, about 100° C. in oxygen atmosphere. The Al film 22 is oxidized by this oxidation treatment to form an AlO_{y} film 23.

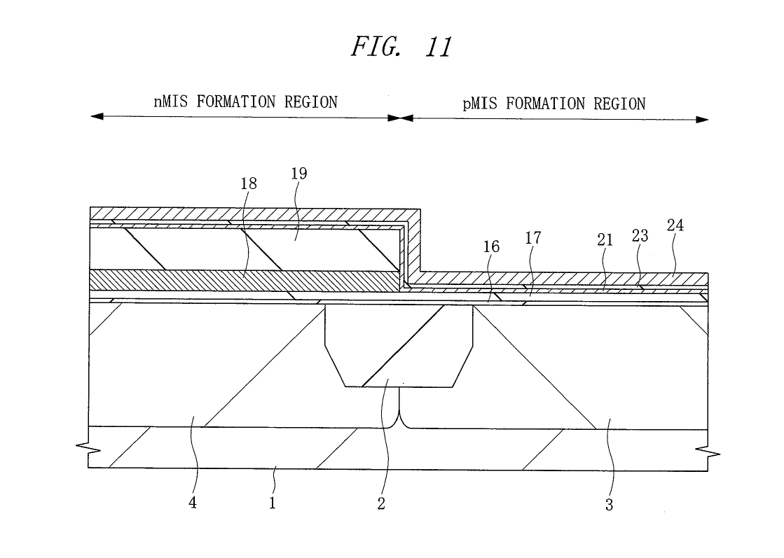

Next, as illustrated in FIG. 11, a second Mo film 24 is formed on the AlO_{y} film 23 by using, for example, a sputtering method. A thickness of the second Mo film 24 is, for example, about 9 nm.

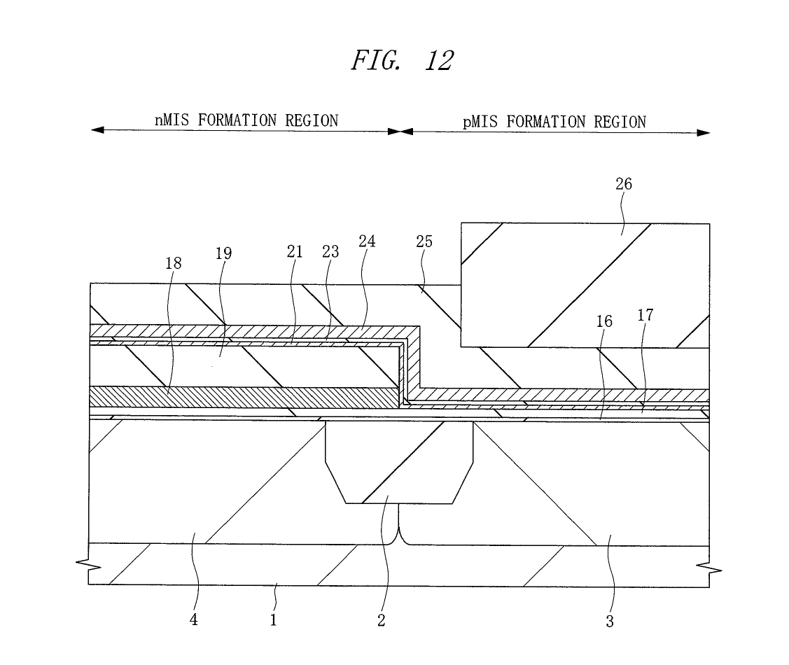

Next, as illustrated in FIG. 12, a SiN film 25 is formed on the second Mo film 24 by using, for example, a CVD method. A thickness of the SiN film 25 is, for example, about 30 nm. Subsequently, a resist pattern 26 covering the pMIS formation region is formed by using a photolithography method.

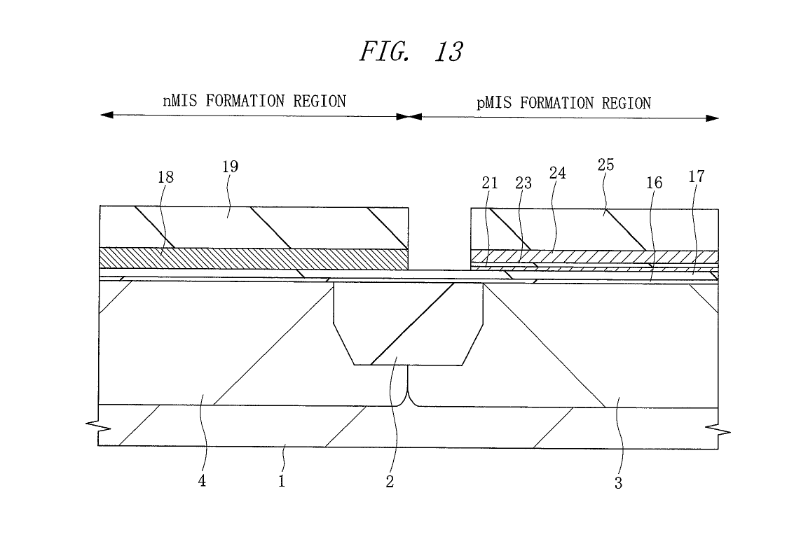

Next, as illustrated in FIG. 13, the SiN film 25, the second Mo film 24, the AlO_{y} film 23, and the first Mo film 21 in the nMIS formation region exposed from the resist pattern 26 are removed with using the resist pattern 26 as a mask by using, for example, a dry etching method, and then, the resist pattern 26 is removed.

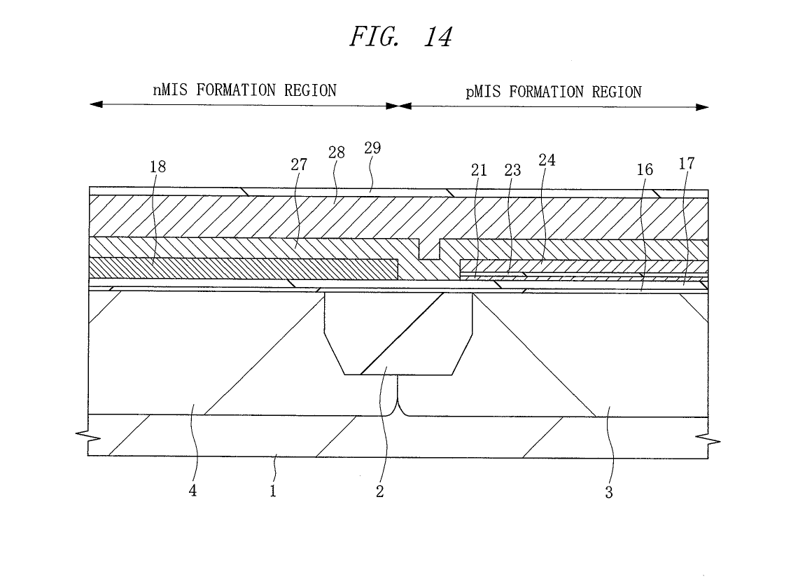

Next, as illustrated in FIG. 14, after the SiN films 19 and 25 are removed, a TiN film 27 is formed on the second Mo film 24 in the pMIS formation region and on the TaSiN film 18 in the nMIS formation region by using, for example, a sputtering method. A thickness of the TiN film 27 is 5 nm or thicker, for example, about 5 to 10 nm. Subsequently, a polycrystalline Si film 28 is formed on the TiN film 27 by using, for example, a CVD method. A thickness of the polycrystalline Si film 28 is, for example, about 20 to 50 nm. While the polycrystalline Si films 28 in the pMIS and the nMIS formation regions may be composed of polycrystalline Si having the same conductivity as each other by doping an n-type impurity or a p-type impurity, the polycrystalline Si film 28 in the pMIS formation region may be composed of polycrystalline Si having p-type conductivity and the polycrystalline Si film 28 in the nMIS formation region may be composed of polycrystalline Si having n-type conductivity. Subsequently, a SiN film 29 is formed on the polycrystalline Si film 28 by using, for example, a sputtering method.

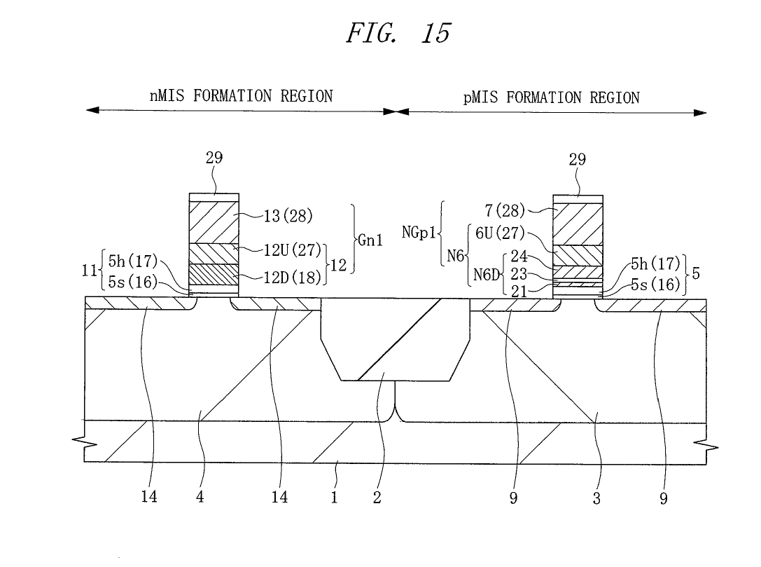

Next, as illustrated in FIG. 15, the gate insulating film 5 and a temporary gate electrode NGp1 are formed in the pMIS formation region and the gate insulating film 11 and the gate electrode Gn1 are formed in the nMIS formation region by using a photolithography method and dry etching method.

The gate insulating film 5 formed in the pMIS formation region is constituted by: the oxide film 5s composed of the SiO₂ film 16; and the high dielectric film 5h composed of the HfSiON film 17. The temporary gate electrode NGp1 is constituted by: a temporary metal gate electrode N6; and the silicon gate electrode 7 composed of the polycrystalline Si film 28, and further, the temporary metal gate electrode N6 is constituted by: a temporary lower-layer metal gate electrode N6D composed of the first Mo film 21, the AlO_{y} film 23, and the second Mo film 24; and the upper-layer metal gate electrode 6U composed of the TiN film 27.

The gate insulating film 11 formed in the nMIS formation region is constituted by: the oxide film 5s composed of the SiO₂ film 16; and the high dielectric film 5h composed of the HfSiON film 17. The gate electrode Gn1 is constituted by: the metal gate electrode 12; and the silicon gate electrode 13 composed of the polycrystalline Si film 28, and further, the metal gate electrode 12 is constituted by: the lower-layer metal gate electrode 12D composed of the TaSiN film 18; and the upper-layer metal gate electrode 12U composed of the TiN film 27.

Next, the p-type extension regions 9 are formed in the pMIS formation region so as to self-align with respect to the temporary gate electrode NGp1 by using a photolithography method and ion implantation method. The p-type extension region 9 is a semiconductor region formed by doping a p-type impurity such as B into the semiconductor substrate 1. Similarly, the n-type extension regions 14 are formed in the nMIS formation region so as to self-align with respect to the gate electrode Gn1 by using a photolithography method and ion implantation method. The n-type extension region 14 is a semiconductor region formed by doping an n-type impurity such as P or As into the semiconductor substrate 1.

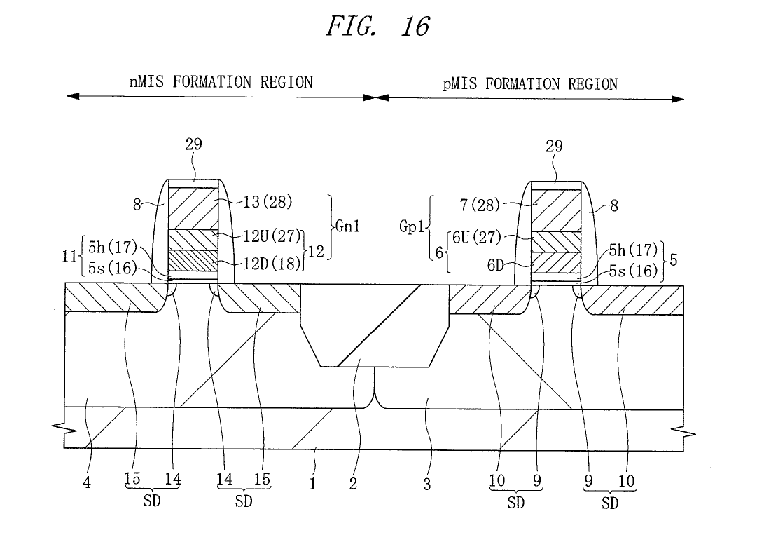

Next, as illustrated in FIG. 16, after an insulating film is formed on the main surface of the semiconductor substrate 1, the insulating film is anisotropically etched by using a dry etching method, so that the sidewalls 8 are formed on sidewalls of each of the temporary gate electrode NGp1 in the pMIS formation region and the gate electrode Gn1 in the nMIS formation region.

Next, the p-type diffusion regions 10 are formed in the pMIS formation region so as to self-align with respect to the temporary gate electrode NGp1 and the sidewalls 8 by using a photolithography method and ion implantation method. The p-type diffusion region 10 is a semiconductor region formed by doping a p-type impurity such as B into the semiconductor substrate 1. Similarly, the n-type diffusion regions 15 are formed in the nMIS formation region so as to self-align with respect to the gate electrode Gn1 and the sidewalls 8 by using a photolithography method and ion implantation method. The n-type diffusion region 15 is a semiconductor region formed by doping an n-type impurity such as P or As into the semiconductor substrate 1.

Next, a thermal treatment is applied to the semiconductor substrate 1. The thermal treatment is applied at a temperature of 600° C. or higher, for example, 1000° C. By this thermal treatment, the first Mo film 21, the AlO_{y} film 23, and the second Mo film 24 are mutually diffused into each other in the pMIS formation region, so that the Mo₁₋ₓAlₓO_{y} film is formed. A thickness of the Mo₁₋ₓAlₓO_{y} film is 3 nm or thicker, for example, about 3 to 10 nm. In this manner, the lower-layer metal gate electrode 6D is composed of the Mo₁₋ₓAlₓO_{y} film, the metal gate electrode 6 is constituted by the lower-layer metal gate electrode 6D and the upper-layer metal gate electrode 6U, and the gate electrode Gp1 is constituted by the metal gate electrode 6 and the silicon gate electrode 7.

Further, by this thermal treatment, the p-type impurities doped into the p-type extension region 9 and the p-type diffusion region 10 in the pMIS formation region are activated, and the n-type impurities doped into the n-type extension region 14 and the n-type diffusion region 15 in the nMIS formation region are activated, so that the source/drain regions SD are formed.

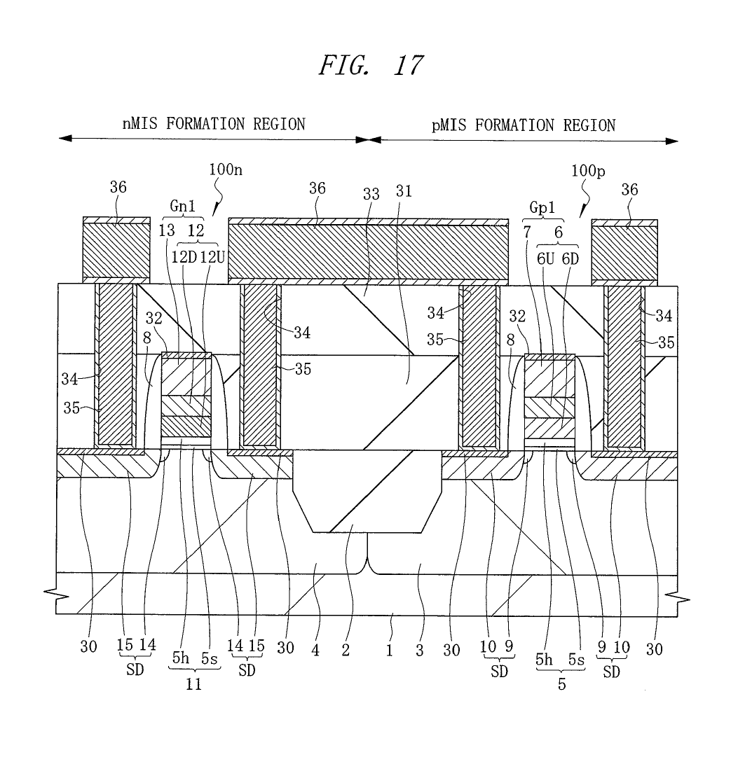

Next, as illustrated in FIG. 17, after a Ni film is formed on the main surface of the semiconductor substrate 1, a thermal treatment is applied to the semiconductor substrate 1. The thermal treatment is applied at a temperature of, for example, 450° C. By this thermal treatment, the monocrystalline Si composing the semiconductor substrate 1 and the Ni film are solid-phase reacted with each other, so that NiSi (nickel silicide) is formed, and subsequently, unreacted Ni is removed by using a mixed solution of H₂SO₄ (sulfuric acid) and H₂O₂ (hydrogen peroxide), so that a NiSi film 30 is formed on surfaces of the source/drain regions SD in the pMIS and nMIS formation regions.

Next, an interlayer insulating film 31, for example, a tetraethoxysilane (TEOS, (Si(OC₂H₅)₄)) film is formed on the main surface of the semiconductor substrate 1 by using, for example, a CVD method, and then, the surface of the interlayer insulating film 31 is polished by using, for example, a chemical mechanical polishing (CMP) method, so that the SiN film 29 formed in each upper layer of the gate electrode Gp1 in the pMIS 100p and the gate electrode Gill in the nMIS 100n is exposed, and further, the SiN film 29 is removed.

Next, after a Ni film is formed on the main surface of the semiconductor substrate 1, a thermal treatment is applied to the semiconductor substrate 1. The thermal treatment is applied at a temperature of, for example, 450° C. By this thermal treatment, the Ni film and the polycrystalline Si film 28 composing the silicon gate electrode 7 of the gate electrode Gp1 in the pMIS 100p are solid-phase reacted with each other, and the Ni film and the polycrystalline Si film 28 composing the silicon gate electrode 13 of the gate electrode Gn1 in the nMIS 100n are solid-phase reacted with each other, so that NiSi is formed, and subsequently, unreacted Ni is removed by using a mixed solution of H₂SO₄ and H₂O₂, so that a NiSi film 32 is formed on a surface of the polycrystalline Si film 28. A thickness of the NiSi film 32 is, for example, about 30 nm. A specific electrical resistance of the polycrystalline Si film 28 is about 1000 μΩ·cm, and a specific electrical resistance of the NiSi film 32 is about 100 to 200 μΩ·cm, and therefore, by forming the NiSi film 32, low electrical resistivity of the silicon gate electrodes 7 and 13 can be achieved.

Next, an interlayer insulating film 33, for example, a TEOS film is formed on the main surface of the semiconductor substrate 1 by using, for example, a CVD method, and then, contact holes 34 are formed in the interlayer insulating films 31 and 33 by using, for example, a photolithography method and dry etching method.

Next, Ti/TiN films are sequentially deposited on the interlayer insulating films 31 and 33 including bottom surfaces and inner walls of the connection holes 34 by using, for example, a sputtering method, so that the Ti/TiN films are formed. The Ti/TiN film has a so-called barrier function for preventing, for example, diffusion of materials buried inside the contact hole 34 in a later step. Subsequently, a W film is formed on the main surface of the semiconductor substrate 1 so as to bury the inside of the contact hole 34 by using, for example, a CVD method. Subsequently, the W film and the Ti/TiN film are polished by using, for example, a CMP method, so that a plug 35 is formed in the contact hole 34.

Subsequently, a Ti/TiN film, an Al film, and a Ti/TiN film are sequentially formed on the main surface of the semiconductor substrate 1 by using, for example, a sputtering method. Subsequently, these films are processed by using a photolithography method and dry etching method, so that wirings 36 are formed. Thereafter, wirings in upper layers are further formed. However, their descriptions are omitted here. By the above steps, the CMIS device constituted by the pMIS 100p and the nMIS 100n is substantially completed.

Note that, in the above-described method of manufacturing the CMIS device, the formation of the Mo₁₋ₓAlₓO_{y} film b_{y} mutually diffusing the first Mo film 21, the AlO_{y} film 23, and the second Mo film 24 into each other is carried out after the formation of the temporary gate electrode NGp1 in the pMIS formation region by using a photolithography method and dry etching method. However, the order of the formations is not limited to this. For example, after the second Mo film 24 is formed on the AlO_{y} film 23 (after the step described above with reference to FIG. 11), the thermal treatment is applied to the semiconductor substrate 1, so that the Mo₁₋ₓAlₓO_{y} film may be formed.

Also, in the above-described method of manufacturing the CMIS device, the NiSi film 30 for achieving the low electrical resistivity is formed on each surface of the source/drain regions SD in the pMIS 100p and the nMIS 100n, and the NiSi film 32 for achieving the low electrical resistivity is formed on each surface of the silicon gate electrode 7 of the gate electrode Gp1 in the pMIS 100p and the silicon gate electrode 13 of the gate electrode Gn1 in the nMIS 100n. However, other silicide-material film such as a PtSi film or a TiSi (titanium silicide) film may be formed.

In this manner, according to the first embodiment, the metal gate electrode 6 of the gate electrode Gp1 in the pMIS 100p is composed of the Me₁₋ₓAlₓO_{y} film (Me is a metal element such as Mo, Ru, or Ir), and each concentration of the Al or O element contained in the Me₁₋ₓAlₓO_{y} film is adjusted, so that a desired work function larger than that of a film composed of a single metal element can be obtained. As a result, a desired threshold voltage in the pMIS 100p can be obtained.

### Second Embodiment

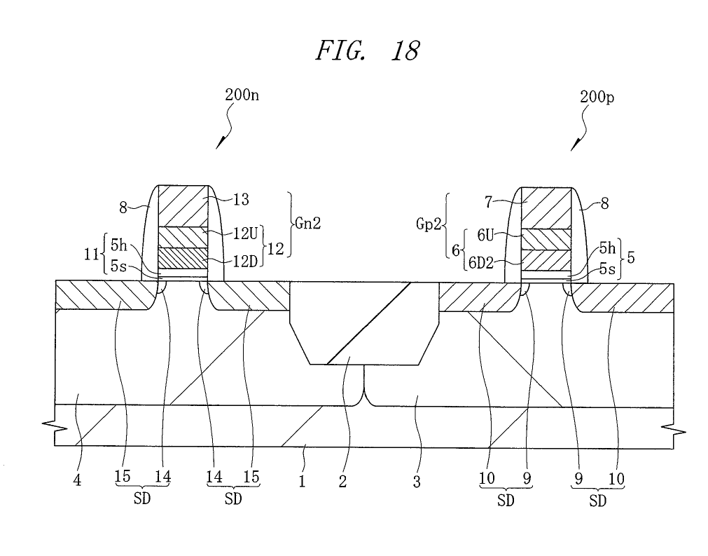

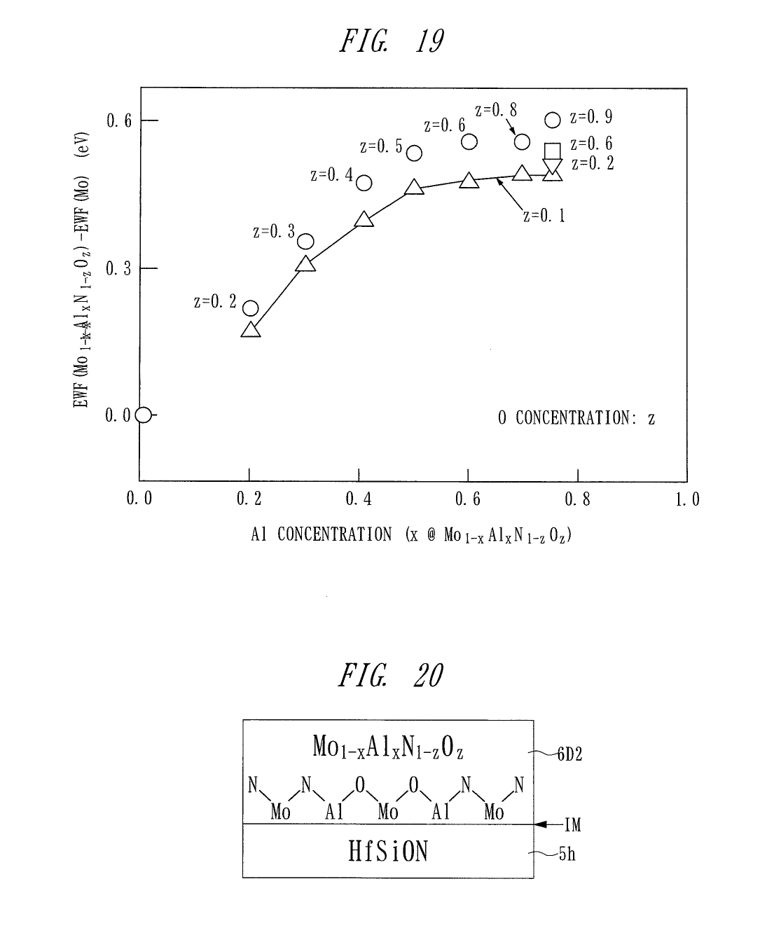

A CMIS device according to a second embodiment will be described with reference to FIGS. 18 to 20. FIG. 18 is a cross-sectional view of a principal part of the CMIS device, FIG. 19 is a graph chart explaining a relation between a work function of a Mo₁₋ₓAlₓN_{1-z}O_{z} film and an Al or O concentration, and FIG. 20 is a schematic diagram illustrating so as to enlarge a part of a gate electrode in a pMIS.

A different point from the above-described first embodiment is a structure of the gate electrode in the pMIS. That is, in the first embodiment, the metal gate electrode 6 constituting the part of the gate electrode Gp1 in the pMIS 100p is composed of the double-layer metal film (the upper-layer metal gate electrode 6U and the lower-layer metal gate electrode 6D), and further, the lower-layer metal gate electrode 6D is composed of the Me₁₋ₓAlₓO_{y} film (Me is a metal element, and 0.2≦x≦0.75, 0.2≦y≦1.5). On the other hand, in the second embodiment, as illustrated in FIGS. 18 and 20, a lower-layer metal gate electrode 6D2 constituting a part of a gate electrode Gp2 in a pMIS 200p is composed of a Me₁₋ₓAlₓN_{1-z}O_{z} film (Me is a metal element, and 0.2≦x≦0.75, 0.1≦z≦0.9). The metal element described as Me is any of, for example, Mo, Ru, and Ir. A configuration of a gate electrode Gn2 in an nMIS 200n according to the second embodiment is the same as that of the gate electrode Gn1 in the nMIS 100n according to the first embodiment.

FIG. 19 illustrates the graph chart explaining dependency of the Al or O concentration with respect to a difference between work functions of a Mo film and the Mo₁-xAlₓN_{1-z}O_{z} film formed by using the Mo element as the metal element. As illustrated in FIG. 19, the work function of the Mo₁₋ₓAlₓN_{1-z}O_{z} film in which Al and O elements are added to a MoN film is larger than that of the MoN film, and further, that of the Mo₁₋ₓAlₓN_{1-z}O_{z} film increases as each concentration of the Al or O element contained in the Mo₁₋ₓAlₓN_{1-z}O_{z} film increases. Therefore, by adjusting each concentration of the Al or O element contained in the Mo₁₋ₓAlₓN_{1-z}O_{z} film, a desired work function of the Mo₁₋ₓAlₓN_{1-z}O_{z} film larger than that of the MoN film can be obtained. As a result, a desired threshold voltage in the pMIS can be obtained.

It is considered that a reason for the larger work function of the Mo₁₋ₓAlₓN_{1-z}O_{z} film than that of the MoN film is because, as illustrated in FIG. 20, a Mo—O—Al—N—Mo bond is formed in a region of the lower-layer metal gate electrode 6D2 within about 0.5 nm distance from an interface “IM” between the lower-layer metal gate electrode 6D2 (Mo₁₋ₓAlₓN_{1-z}O_{z} film) and the gate insulating film 5h, so that the Mo—O bond and the Mo—N bond are enhanced. The inventors of the present application confirmed an increasing concentration gradient of the Al and O concentrations in a vicinity of the interface IM in the Mo₁₋ₓAlₓN_{1-z}O_{z} film by SIMS analysis.

Also, as seen from the above-described FIG. 19, the work function of the Mo₁₋ₓAlₓN_{i-z}O_{z} film depends on the Al concentration more than the O concentration. That is, the O concentration is low when the Al concentration in the Mo₁₋ₓAlₓN_{1-z}O_{z} film is low, and the O concentration is increased as the Al concentration is increased. Therefore, in order to add a large amount of the O element to the Mo₁₋ₓAlₓN_{1-z}O_{z} film for forming the Mo—O—Al—N—Mo bond, it is required to increase the Al concentration in the Mo₁₋ₓAlₓN_{1-z}O_{z} film.

Note that it is mostly preferable to obtain the ratio “x” of the Al element and the ratio “z” of the O element over the entire Mo₁-xAlₓN_{1-z}O_{z} film. However, the ratios may be obtained at least in the region of the lower-layer metal gate electrode 6D2 within about 0.5 nm distance from the interface IM between the lower-layer metal gate electrode 6D2 and the gate insulating film 5h.

Further, when the sidewalls 8 formed on sidewalls of the gate electrode Gp2 are composed of a SiN film, the adhesiveness between the metal gate electrode 6 and the sidewall 8 is improved by using a conductive material (Me₁₋ₓAlₓN_{1-z}O_{z} film) containing N element for a material of the metal gate electrode 6 constituting the part of the gate electrode Gp2 in the pMIS 200p. Even when miniaturization is advanced to further shorten a width (sidewall length) of the sidewall 8, peel-off of the sidewall 8 can be suppressed, and the sidewall 8 having a predetermined width can be formed, and therefore, stable transistor characteristics can be obtained in the pMIS 200p.

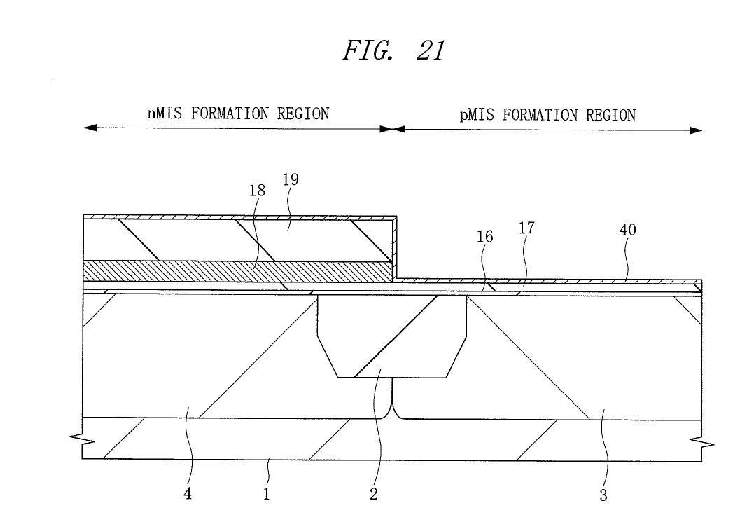

Next, a method of manufacturing the CMIS device according to the second embodiment will be described in the order of steps with reference to FIGS. 21 to 29. FIGS. 21 to 29 are cross-sectional views of a principal part of the CMIS device. Note that the manufacturing steps (steps described with reference to FIGS. 4 to 7 in the above-described first embodiment) from the formations of the SiO₂ film 16 and the HfSiON film 17 on the main surface of the semiconductor substrate 1 to the formation of the TaSiN film 18 composing the lower-layer metal gate electrode 12D of the gate electrode Gn2 in the nMIS formation region are the same as those of the first embodiment. Therefore, their descriptions are omitted.

As continued from the manufacturing step described with reference to FIG. 7 in the above-described first embodiment and illustrated in FIG. 21, a first Mo₂N film 40 is formed on the HfSiON film 17 in the pMIS formation region and on the SiN film 19 in the nMIS formation region by using, for example, a sputtering method. A thickness of the first Mo₂N film 40 is, for example, about 1 nm.

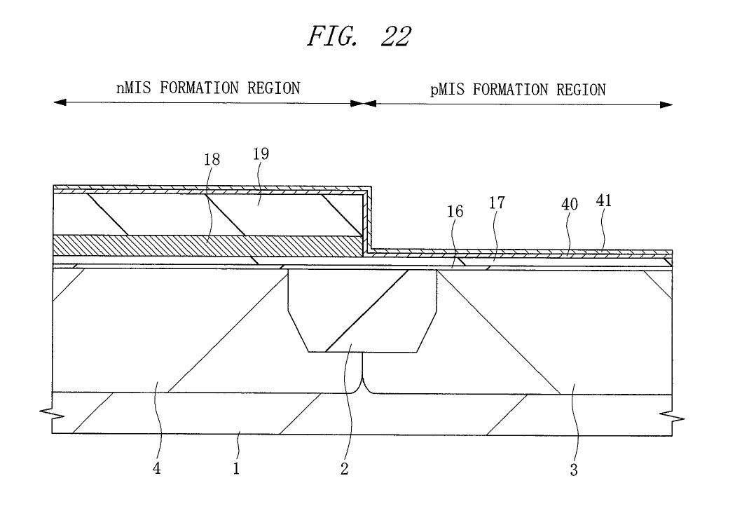

Next, as illustrated in FIG. 22, an AlN, film 41 is formed on the first Mo₂N film 40 by using, for example, a sputtering method. A thickness of the AlN, film 41 is, for example, about 0.1 to 1 nm.

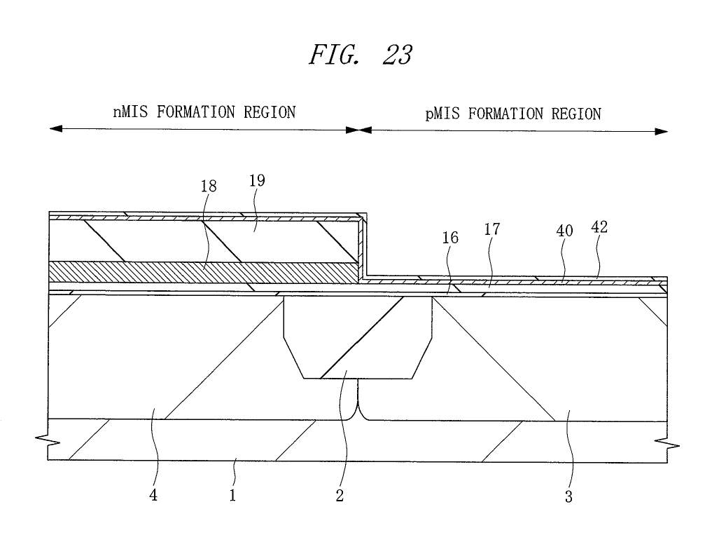

Next, as illustrated in FIG. 23, an oxidation treatment is applied to the semiconductor substrate 1. The oxidation treatment is applied at 400° C. or lower, for example, about 100° C. in oxygen atmosphere. The AlN, film 41 is oxidized by this oxidation treatment to form an AlN_{1-z}O_{z} film 42.

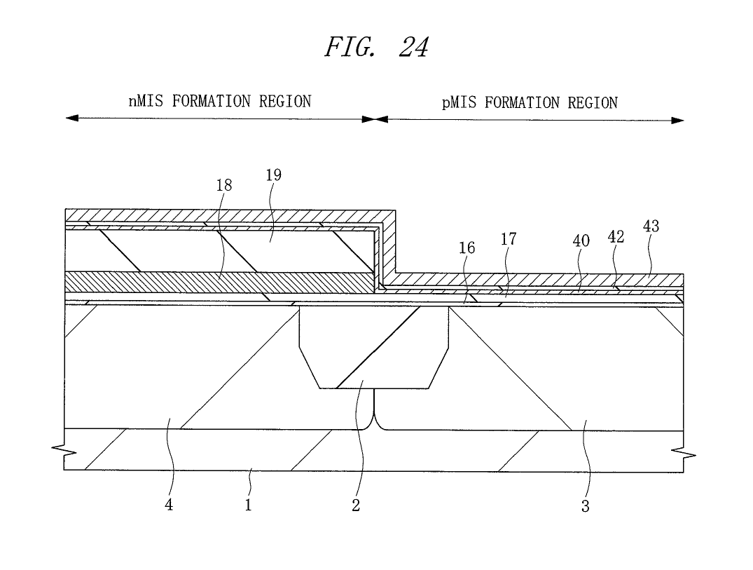

Next, as illustrated in FIG. 24, a second Mo₂N film 43 is formed on the film 42 by using, for example, a sputtering method. A thickness of the second Mo₂N film 43 is, for example, about 9 nm.

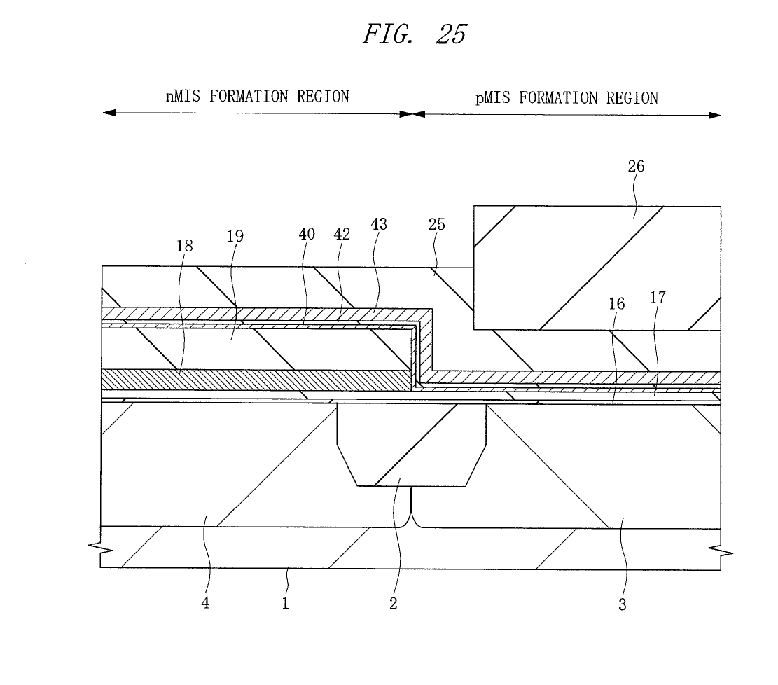

Next, as illustrated in FIG. 25, a SiN film 25 is formed on the second Mo₂N film 43 by using, for example, a CVD method. A thickness of the SiN film 25 is, for example, about 30 nm. Subsequently, a resist pattern 26 covering the pMIS formation region is formed by using a photolithography method.

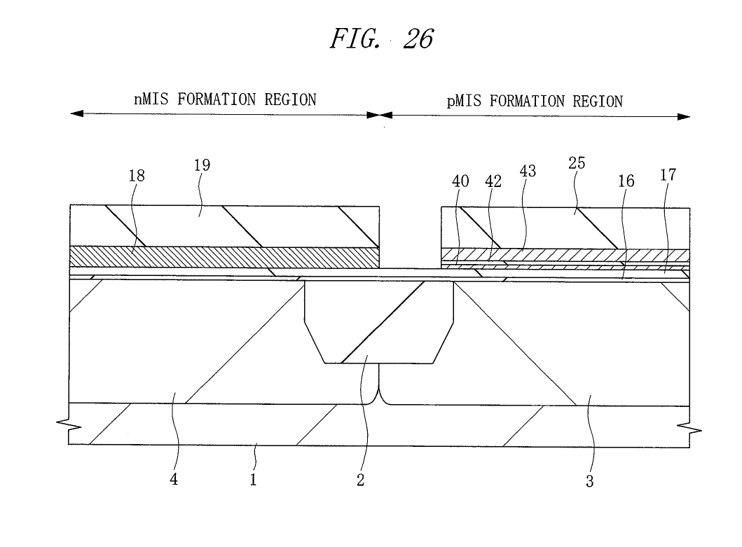

Next, as illustrated in FIG. 26, the SiN film 25, the second Mo₂N film 43, the AlN_{1-z}O_{z} film 42, and the first Mo₂N film 40 in the nMIS formation region exposed from the resist pattern 26 are removed with using the resist pattern 26 as a mask by using, for example, a dry etching method, and then, the resist pattern 26 is removed.

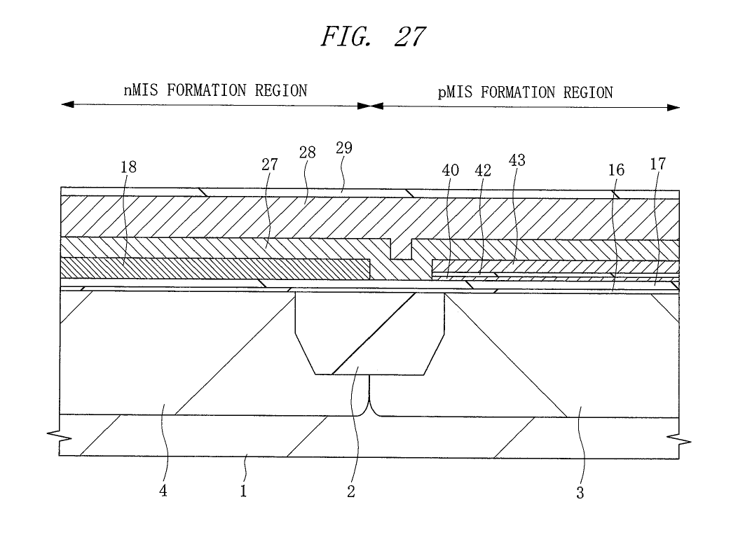

Next, as illustrated in FIG. 27, the SiN films 19 and 25 are removed, and then, a TiN film 27 is formed on the second Mo₂N film 43 in the pMIS formation region and on the TaSiN film 18 in the nMIS formation region by using, for example, a sputtering method. A thickness of the TiN film 27 is 5 nm or thicker, for example, about 5 to 10 nm. Subsequently, a polycrystalline Si film 28 is formed on the TiN film 27 by using, for example, a CVD method. A thickness of the polycrystalline Si film 28 is, for example, about 20 to 50 nm. While the polycrystalline Si films 28 in the pMIS and nMIS formation regions may be composed of polycrystalline Si having the same conductivity as each other by doping an n-type impurity or a p-type impurity, the polycrystalline Si film 28 in the pMIS formation region may be composed of polycrystalline Si having p-type conductivity and the polycrystalline Si film 28 in the nMIS formation region may be composed of polycrystalline Si having n-type conductivity. Subsequently, a SiN film 29 is formed on the polycrystalline Si film 28 by using, for example, a sputtering method.

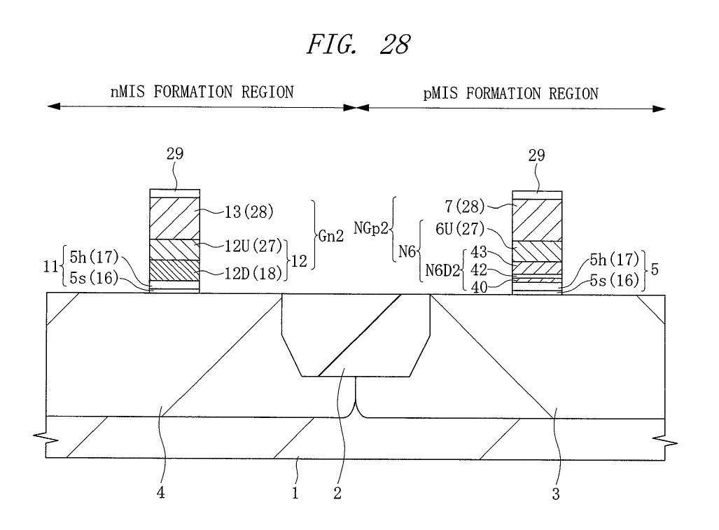

Next, as illustrated in FIG. 28, similarly to the first embodiment, the gate insulating film 5 and a temporary gate electrode NGp2 are formed in the pMIS formation region and the gate insulating film 11 and a gate electrode Gn2 are formed in the nMIS formation region by using a photolithography method and dry etching method. The temporary gate electrode NGp2 formed in the pMIS formation region is constituted by: a temporary metal gate electrode N6; and the silicon gate electrode 7. Further, the temporary metal gate electrode N6 is constituted by: a temporary lower-layer metal gate electrode N6D2 composed of the first Mo₂N film 40, the AlN_{1-z}O_{z} film 42, and the second Mo₂N film 43; and the upper-layer metal gate electrode 6U composed of the TiN film 27.

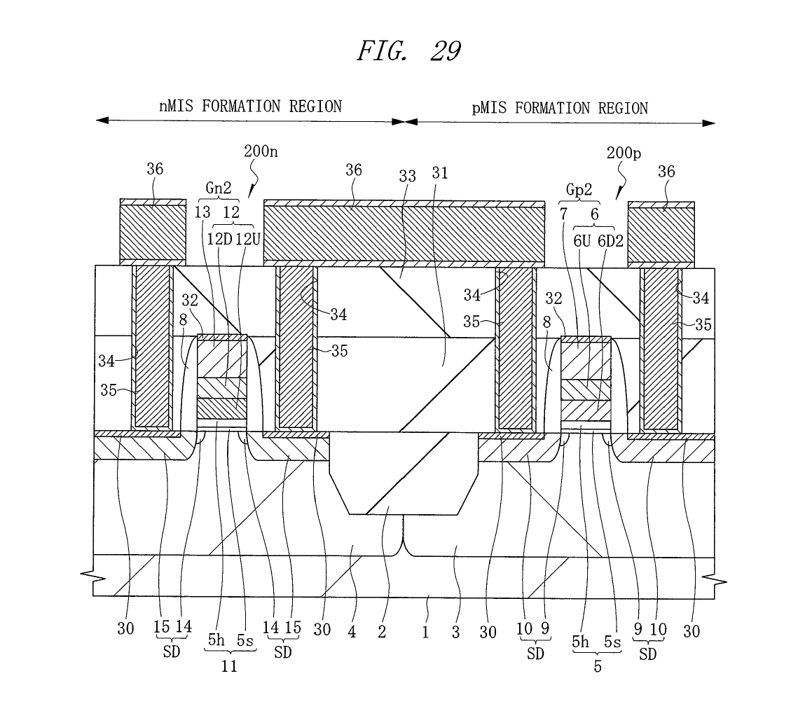

Next, as illustrated in FIG. 29, similarly to the first embodiment, the p-type extension region 9, the sidewall 8, and the p-type diffusion region 10 in the pMIS 200p are formed, and the n-type extension region 14, the sidewall 8, and the n-type diffusion region 15 in the nMIS 200n are formed.

Next, a thermal treatment is applied to the semiconductor substrate 1. The thermal treatment is applied at a temperature of 600° C. or higher, for example, 1000° C. By this thermal treatment, the first Mo₂N film 40, the AlN_{1-z}O_{z} film 42, and the second Mo₂N film 43 are mutually diffused into each other in the pMIS formation region, so that the Mo₁₋ₓAlₓN_{1-z}O_{z} film is formed. A thickness of the Mo₁₋ₓAlₓN_{1-z}O_{z} film is 3 nm or thicker, for example, about 3 to 10 nm. In this manner, the lower-layer metal gate electrode 6D2 is composed of the Mo₁₋ₓAlₓN_{1-z}O_{z} film, the metal gate electrode 6 is constituted by the lower-layer metal gate electrode 6D2 and the upper-layer metal gate electrode 6U, and the gate electrode Gp2 is constituted by the metal gate electrode 6 and the silicon gate electrode 7.

Further, by this thermal treatment, the p-type impurities doped into the p-type extension region 9 and the p-type diffusion region 10 in the pMIS formation region are activated, and the n-type impurities doped into the n-type extension region 14 and the n-type diffusion region 15 in the nMIS formation region are activated, so that the source/drain regions SD are formed.

Then, similarly to the first embodiment, the NiSi film 30 is formed on surfaces of the source/drain regions SD in the pMIS and nMIS formation regions, and the NiSi film 32 is formed on surfaces of the silicon gate electrodes 7 and 13. Then, the plugs 35, the wirings 36, and others are formed, so that the CMIS device is substantially completed.

Incidentally, a specific electrical resistance of the Mo₁₋ₓAlₓN_{1-z}O_{z} film composing the lower-layer metal gate electrode 6D of the metal gate electrode 6 is about 300 to 500 μΩ·cm, and a specific electrical resistance of the TiN film 27 composing the upper-layer metal gate electrode 6U is about 100 μΩ·cm, and therefore, the resistance of the Mo₁₋ₓAlₓN_{1-z}O_{z} film is higher than that of the TiN film 27. However, since a specific electrical resistance of the polycrystalline Si film 28 composing the silicon gate electrode 7 is about 1000 μΩ·cm, the resistance of the silicon gate electrode 7 determines a conductivity of the gate electrode Gp2 in entire view of the gate electrode Gp2. Note that, in the second embodiment, since the NiSi film 32 having a specific electrical resistance of about 100 to 200 μΩ·cm is formed on the polycrystalline Si film 28 composing the silicon gate electrode 7, the gate electrode Gp2 has a high conductivity.

Also, in the above-described method of manufacturing the CMIS device, the formation of the Mo₁₋ₓAlₓN_{1-z}O_{z} film by mutually diffusing the first Mo₂N film 40, the AlN_{1-z}O_{z} film 42, and the second Mo₂N film 43 into each other is carried out after the formation of the temporary gate electrode NGp2 in the pMIS formation region by using a photolithography method and dry etching method. However, the order of the formations is not limited to this. For example, after the second Mo₂N film 43 is formed on the AlN_{1-z}O_{z} film 42 (after the step described above with reference to FIG. 23), the thermal treatment is applied to the semiconductor substrate 1, so that the Mo₁₋ₓAlₓN_{1-z}O_{z} film may be formed.

Further, in the above-described method of manufacturing the CMIS device, the NiSi film 30 for achieving the low electrical resistivity is formed on each surface of the source/drain regions SD in the pMIS 200p and the nMIS 200n, and the NiSi film 32 for achieving the low electrical resistivity is formed on each surface of the silicon gate electrode 7 of the gate electrode Gp2 in the pMIS 200p and the silicon gate electrode 13 of the gate electrode Gn2 in the nMIS 200n. However, other silicide-material film such as a PtSi film or a TiSi film may be formed.

In this manner, according to the second embodiment, the metal gate electrode 6 of the gate electrode Gp2 in the pMIS 200p is composed of the Me₁₋ₓAlₓN_{1-z}O_{z} film (Me is a metal element such as Mo, Ru, or Ir), and each concentration of the Al or O element contained in the Me₁₋ₓAlₓN_{1-z}O_{z} film is adjusted, so that a desired work function larger than that of a film composed of a single metal element can be obtained. As a result, a desired threshold voltage in the pMIS 200p can be obtained.

In the foregoing, the invention made by the inventors has been concretely described based on the embodiments. However, it is needless to say that the present invention is not limited to the foregoing embodiments and various modifications and alterations can be made within the scope of the present invention.

The present invention can be widely used in the manufacturing industry of manufacturing a semiconductor device, more particularly, a semiconductor device having a gate length of 30 nm or shorter.

What is claimed is:

1. A semiconductor device having a p-channel-type field-effect transistor in which a metal gate electrode and a gate insulating film composed of a high dielectric film having a higher dielectric constant than that of SiO₂ are provided on a main surface of a semiconductor substrate, wherein
the metal gate electrode is composed of a conductive film with a Me₁₋ₓAlₓO_{y} composition having a bond composed of a metal element, Al element, and O element,
a ratio x of the Al element is 0.2 or larger and 0.75 or smaller, and
a ratio y of the O element is 0.2 or larger and 1.5 or smaller.

2. A semiconductor device having a p-channel-type field-effect transistor in which a metal gate electrode and a gate insulating film composed of a high dielectric film having a higher dielectric constant than that of SiO₂ are provided on a main surface of a semiconductor substrate, wherein
the metal gate electrode is composed of a conductive film with a Me₁₋ₓAlₓN_{1-z}O_{z} composition having a bond composed of a metal element, Al element, N element, and O element,
a ratio x of the Al element is 0.2 or larger and 0.75 or smaller, and
a ratio z of the O element is 0.1 or larger and 0.9 or smaller.

3. The semiconductor device according to claim 1, wherein
the metal element is Mo, Ru, or Ir.

4. The semiconductor device according to claim 1, wherein
a concentration of the Al element and a concentration of the O element have a concentration gradient maximized at a vicinity of an interface between the gate insulating film and the metal gate electrode.

5. The semiconductor device according to claim 1, wherein
A thickness of the metal gate electrode is 3 nm or thicker.

6. The semiconductor device according to claim 1, wherein
a metal nitride film is formed on the metal gate electrode.

7. The semiconductor device according to claim 1, wherein
a metal nitride film is formed on the metal gate electrode, and
a polycrystalline Si film is formed on the metal nitride film.

8. The semiconductor device according to claim 1, wherein
the high dielectric film is a HfO₂ film, a HfON film, a HfSiO film, or a HfSiON film.

9. The semiconductor device according to claim 1, wherein
an oxide film having a thickness of 1 nm or thinner is formed between the semiconductor substrate and the high dielectric film.

10. A method of manufacturing a semiconductor device having a p-channel-type field-effect transistor on a main surface of a semiconductor substrate comprising the steps of:
(a) forming a gate insulating film on the main surface of the semiconductor substrate, the gate insulating film being composed of a high dielectric film having a higher dielectric constant than that of SiO₂;
(b) sequentially forming a first metal film and an Al film on the gate insulating film;
(c) applying a thermal treatment to the semiconductor substrate at a temperature of 400° C. or lower for oxidizing the Al film to form an AlO_{y} film;
(d) forming a second metal film on the AlO_{y} film; and
(e) applying a thermal treatment to the semiconductor substrate at a temperature of 600° C. or higher to form a metal gate electrode on the gate insulating film, the metal gate electrode being composed of a conductive film with a Me₁₋ₓAlₓO_{y} composition.

11. The method of manufacturing the semiconductor device according to claim 10, wherein
a ratio x of an Al element in the conductive film is 0.2 or larger and 0.75 or smaller; and
a ratio y of an O element in the conductive film is 0.2 or larger and 1.5 or smaller.

12. The method of manufacturing the semiconductor device according to claim 10 further comprising the step of, between the steps of (d) and (e):
(f) forming a metal nitride film on the second metal film, and forming a polycrystalline Si film on the metal nitride film.

13. A method of manufacturing a semiconductor device having a p-channel-type field-effect transistor on a main surface of a semiconductor substrate comprising the steps of:
(a) forming a gate insulating film on the main surface of the semiconductor substrate, the gate insulating film being composed of a high dielectric film having a higher dielectric constant than that of SiO₂;
(b) sequentially forming a first metal nitride film and an AlN_{z} film on the gate insulating film;
(c) applying a thermal treatment to the semiconductor substrate at a temperature of 400° C. or lower for oxidizing the AlN, film to form an AlN_{1-z}O_{z} film;
(d) forming a second metal nitride film on the AlN_{1-z}O_{z} film; and
(e) applying a thermal treatment to the semiconductor substrate at a temperature of 600° C. or higher to form a metal gate electrode on the gate insulating film, the metal gate electrode being composed of a conductive film with a Me₁₋ₓAlₓN_{1-z}O_{z} composition.

14. The method of manufacturing the semiconductor device according to claim 13, wherein
a ratio x of an Al element in the conductive film is 0.2 or larger and 0.75 or smaller; and
a ratio z of an O element in the conductive film is 0.1 or larger and 0.9 or smaller.

15. The method of manufacturing the semiconductor device according to claim 13 further comprising the step of, between the steps of (d) and (e):
(f) forming a third metal nitride film on the second metal nitride film, and forming a polycrystalline Si film on the third metal nitride film.

16. The method of manufacturing the semiconductor device according to claim 10, wherein
the Me element in the conductive film is Mo, Ru, or Ir.

17. The method of manufacturing the semiconductor device according to claim 10, wherein
a concentration of the Al element in the conductive film and a concentration of the O element in the conductive film have a concentration gradient maximized at a vicinity of an interface between the gate insulating film and the metal gate electrode.

18. The method of manufacturing the semiconductor device according to claim 10, wherein
A thickness of the metal gate electrode is 3 nm or thicker.

19. The method of manufacturing the semiconductor device according to claim 10, wherein
the high dielectric film is a HfO₂ film, a HfON film, a HfSiO film, or a HfSiON film.

20. The method of manufacturing the semiconductor device according to claim 10 further comprising the step of, prior to the step of (a):
(g) forming an oxide film having a thickness of 1 nm or thinner on the main surface of the semiconductor substrate.
